(19) United States
(12) Patent Application Publication
(10) Pub. No.: US 2020/0006654 A1
(43) Pub. Date: Jan. 2, 2020

(54) NON-VOLATILE MEMORY AND FABRICATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventors: Min-Hwa CHI, Shanghai (CN); Zhong Shan HONG, Shanghai (CN); Zhan YING, Shanghai (CN)

(21) Appl. No.: 16/454,576

(22) Filed: Jun. 27, 2019

(30) Foreign Application Priority Data
Jun. 27, 2018 (CN) 201810679813.6

(51) Int. Cl. H01L 45/00; C23C 16/02; C23C 16/26

(52) U.S. Cl. CPC H01L 45/149; H01L 45/1253; H01L 45/1683; C23C 16/26; H01L 45/1233; C23C 16/0272; H01L 45/1616

(57) ABSTRACT

Non-volatile memory and fabrication methods are provided. An exemplary fabrication method includes providing a base substrate; forming a first conductive layer on the base substrate; forming an interlayer dielectric layer on the first conductive layer; forming a plurality of through holes exposing the first conductive layer in the interlayer dielectric layer; forming a catalyst layer on at least one of sidewall surfaces and bottom surfaces of the through holes; forming a carbon nanotube layer in the through holes by a catalytic chemical vapor deposition process; and forming a second conductive layer on the carbon nanotube layer and a portion of the interlayer dielectric layer.

### CROSS-REFERENCES TO RELATED APPLICATIONS

This application claims the priority of Chinese patent application No. 201810679813.6, filed on Jun. 27, 2018, the entirety of which is incorporated herein by reference.

### FIELD OF THE DISCLOSURE

The present disclosure generally relates to the field of semiconductor manufacturing and, more particularly, relates to non-volatile memory and fabrication methods.

### BACKGROUND

Memory is an important component of most electronic products, including read-only memory (ROM), programmable read-only memory (PROM), electrically programmable read-only memory (EPROM), electrically erasable programmable read-only memory (EEPROM, also known as flash memory), dynamic random access memory (DRAM), and static random access memory (SRAM). Some of these memory are non-volatile (data can be maintained without continuous power supply, i.e., data is not lost after power-off). The disadvantage of the non-volatile memory is that it cannot be erased multiple times (such as ROM and PROM). Some of these memory are volatile (for example, DRAM and SRAM). The volatile memory have the disadvantage of high energy consumption. Some of these memory are non-volatile and can be erased multiple times. But the disadvantage is that the access speed is slow. To overcome these shortcomings of the traditional memory, many new types of memory have emerged, such as magnetic random access memory (MRAM), ferroelectric random access memory (FRAM), phase change memory (PCM), etc. However, these new types of memory still have a low access speed or a low storage density.

As we all know, the goal pursued by microelectronic technology is to make products “smaller, faster, and colder”, in particular, smaller in size, faster in speed, and lower in energy consumption. Since the 1960s, the integration level of electronic chips has continued to grow geometrically following the Moore's Law. According to the Moore's Law, by 2020, the current “Top Down” manufacturing technology, i.e., lithography (LIGA), will be unable to further increase the integration level of chips due to reaching the limited line width (tens of nanometers). Thus, the development of electronic devices has encountered bottlenecks. As a major component in electronic devices, the storage density and access speed of the memory need to be correspondingly increased and the energy consumption of the memory needs to be correspondingly reduced to meet the technical requirements of the nanoelectronic era.

However, the performance of existing memory needs to be further improved. The disclosed methods and memory devices are directed to solve one or more problems set forth above and other problems in the art.

### BRIEF SUMMARY OF THE DISCLOSURE

One aspect of the present disclosure includes a method for fabricating a non-volatile memory. The method includes providing a base substrate; forming a first conductive layer on the base substrate; forming an interlayer dielectric layer on the first conductive layer; forming a plurality of through holes exposing the first conductive layer in the interlayer dielectric layer; forming a catalyst layer on at least one of sidewall surfaces and bottom surfaces of the through holes; forming a carbon nanotube layer in the through holes by a catalytic chemical vapor deposition process; and forming a second conductive layer on the carbon nanotube layer and a portion of the interlayer dielectric layer.

Another aspect of the present disclosure includes a non-volatile memory. The non-volatile memory includes a base substrate; a first conductive layer formed on the base substrate; an interlayer dielectric layer formed on the base substrate and the first conductive layer, wherein the interlayer dielectric layer contains a plurality of through holes on the first conductive layer; a carbon nanotube layer formed in the through holes; a catalyst layer formed on at least one of sidewall surfaces and bottom surfaces of the through holes and around the carbon nanotube layer; and a second conductive layer formed on the carbon nanotube layer and a portion of the interlayer dielectric layer.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a non-volatile memory;

FIGS. 2-10 illustrate structures corresponding to certain stages during an exemplary fabrication process of a non-volatile memory consistent with various disclosed embodiments;

FIGS. 11-16 illustrate structures corresponding to certain stages during another exemplary fabrication process of a non-volatile memory consistent with various disclosed embodiments;

FIGS. 17-22 illustrate structures corresponding to certain stages during another exemplary fabrication process of a non-volatile memory consistent with various disclosed embodiments; and

FIG. 23 illustrates an exemplary fabrication process of a non-volatile memory consistent with various disclosed embodiments.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

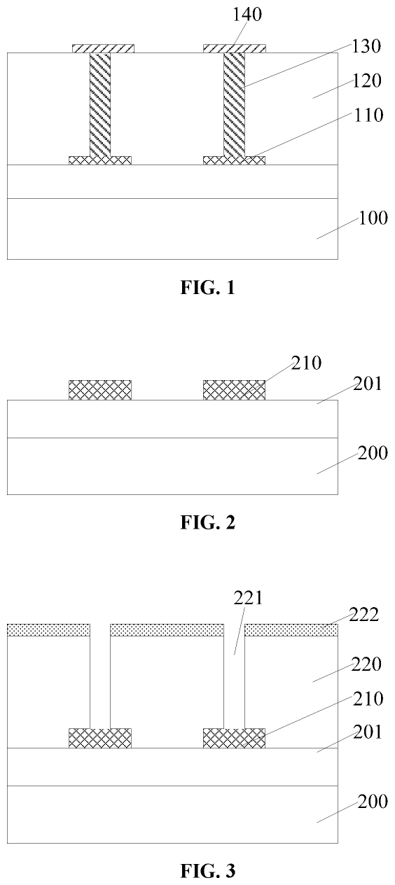

FIG. 1 illustrates a non-volatile memory. As shown in FIG. 1, the non-volatile memory includes a base substrate 100; a first conductive layer 110 on the base substrate 100; and an interlayer dielectric layer 120 on the base substrate 100 and the first conductive layer 110. The interlayer dielectric layer 120 contains a plurality of through holes. The non-volatile memory also includes a carbon nanotube layer 130 formed in the through holes; and a second conductive layer 140 on the carbon nanotube layer 130 and a portion of the interlayer dielectric layer 120.

During the operation of such a non-volatile random access memory, by changing the voltage applied between the first conductive layer 110 and the second conductive layer 140, the distance between the carbon nanotubes is changed, thereby changing the resistance of the carbon nanotube layer 130. Accordingly, the carbon nanotube layer 130 may exhibit a high resistance state or a low resistance state.

The process for forming the carbon nanotube layer 130 includes forming carbon nanotubes; mixing the carbon nanotubes with a spin-coating liquid; and spin-coating the mixture of the carbon nanotubes and the spin-coating liquid in the through holes. Then, a curing process is performed; and the carbon nanotube layer 130 is formed in the through holes.

However, the carbon nanotubes are mixed in the spin-coating liquid, and the different carbon nanotubes are randomly distributed. Therefore, after spin-coating the mixture of the carbon nanotubes and the spin-coating liquid in the plurality of through holes, the distributions of the carbon nanotubes in different through holes are substantially different. Thus, the electrical properties of the carbon nanotube layer 130 in different through holes are significantly different. Accordingly, the differences in the on-state voltages of the carbon nanotube layer 130 in different through holes are substantially large. In particular, when a certain on-state voltage is applied between the first conductive layer 110 and the second conductive layer 140, carbon nanotubes in some of the through holes exhibits a low resistance state, but the resistance values of the carbon nanotubes 130 in some of the through holes do not reach the low resistance state. Correspondingly, the differences in the off-state voltages required for the carbon nanotubes 130 in different through holes are also substantially large. Thus, the performance of the non-volatile memory may be not as desired.

The present disclosure provides a non-volatile memory and a method for forming a non-volatile memory. The method may include forming a catalyst layer on at least one of a sidewall surface and a bottom of a through hole; forming a carbon nanotube layer in the through hole by a catalytic chemical vapor deposition method; and forming a second conductive layer on the carbon nanotube layer and a portion of the interlayer dielectric layer. The method may improve the performance of the non-volatile memory.

FIG. 23 illustrates an exemplary fabrication process of a non-volatile memory. FIGS. 2-10 illustrate structures corresponding to certain stages during the exemplary process for forming a nonvolatile memory consistent to various disclosed embodiments.

As shown in FIG. 23, at the beginning of the fabrication process, a base substrate with certain structures is provided (S101). FIG. 2 illustrates a corresponding structure.

As shown in FIG. 2, a base substrate 200 is provided. A first conductive layer 210 may be formed on a surface of the base substrate 200.

The base substrate 200 may be made of a semiconductor material, such as silicon, germanium, or silicon germanium, etc. The base substrate 200 may also include at least one semiconductor structure, such as a PMOS transistor, an NMOS transistor, a CMOS transistor, a capacitor, a resistor, or an inductor, etc. The surface of the base substrate 200 may also have a bottom dielectric layer 201. The bottom dielectric layer 201 may be made of silicon oxide, or a low-K dielectric material (K is less than 3.9 and greater than 2.6), etc.

The first conductive layer 210 may be formed on a portion of the base substrate 200. In particular, the first conductive layer 210 may be formed on a portion of the bottom dielectric layer 201. The first conductive layer 210 may be made of a metal, such as aluminum, or copper, etc. The material of the first conductive layer 210 may also be an alloy material, such as copper aluminum alloy, etc. The first conductive layer 210 may be electrically connected to a device in the base substrate 200. For example, the first conductive layer 210 may be connected to a source/drain region of a MOS transistor through a conductive plug passing through the bottom dielectric layer 201.

Returning to FIG. 23, after forming the first conductive layer, an interlayer dielectric layer may be formed (S102). FIG. 3 illustrates a corresponding structure.

As shown in FIG. 3, an interlayer dielectric layer 220 may be formed on the base substrate 200 and the first conductive layer 210. A plurality of through holes 221 may be formed in the interlayer dielectric layer 220. The through holes 221 may expose the surface of the first conductive layer 210.

The interlayer dielectric layer 220 may be made of a low-k dielectric material (a low-K dielectric material refers to a dielectric material having a relative dielectric constant greater than 2.6 and less than 3.9), or an ultra-low-K dielectric material (an ultra-low-k dielectric material refers to a dielectric material having a relative dielectric constant smaller than 2.6), or silicon oxide, etc. When the interlayer dielectric layer 220 is made of a low-K dielectric material or an ultra-low-K dielectric material, the material of the interlayer dielectric layer 220 may be SiOH, SiCOH, fluorine-doped silicon dioxide (FSG), boron-doped silicon dioxide (BSG), phosphor doped silicon dioxide (PSG), phosphor and boron-doped silica (BPSG), hydrogenated silsesquioxane (HSQ, (HSiO1.5)ₙ), or methylsilsesquioxane (MSQ, (CH3SiO1.5)ₙ), etc. In one embodiment, the interlayer dielectric layer 220 is made of silicon oxide. The interlayer dielectric layer 220 may also be formed on the bottom dielectric layer 201.

In one embodiment, the size of the opening of a through hole 221 may be in a range of approximately 5 nm-30 nm; and the height of the through hole 221 may be in a range of 45 nm-52 nm. The size of the through holes 221 may be substantially small, it may facilitate to improve the integration level of the non-volatile memory.

In one embodiment, the through hole 221 may be cylindrical-shaped; and the radial direction of the through hole 221 may be parallel to the surface of the base substrate 200. In some embodiments, the through holes may have other appropriate shapes.

The method for forming the through holes 221 may include forming a through hole mask layer 222 on a surface of the interlayer dielectric layer 220. The through hole mask layer 222 may have mask openings passing through the through hole mask layer 222. The mask openings may be located on the interlayer dielectric layer 220. The interlayer dielectric layer 220 at the bottoms of the mask openings may be etched by using the through hole mask layer 222 as a mask until the surface of the first conductive layer 210 is exposed.

The through hole mask layer 222 may be a hard mask layer. In one embodiment, the material of the through mask layer 222 is TiN.

In one embodiment, after forming the through holes 221, the through hole mask layer 222 may be kept; and the through hole mask layer 222 may be removed during the subsequent polishing process on the carbon nanotube layer. In some embodiments, the through hole mask layer may be removed prior to forming a catalyst layer.

After forming the interlayer dielectric layer, a catalyst layer may be formed on at least one of the sidewall surfaces of the through holes and the bottoms of the through holes. In particular, the catalyst layer may be formed only on sidewall surfaces of the through holes, or only on the bottoms of the through holes, or on both the sidewall surfaces and the bottoms of the through holes.

In one embodiment, for illustrative purposes the catalyst layer may be formed on the sidewall surfaces of the through holes 221; and may not be formed on the bottom surfaces of the through holes 221. The method for forming the catalyst layer may include implanting catalytic ions into sidewall surfaces and bottom surfaces of the through holes 221 by an ion implantation process to form an initial catalyst layer on sidewall surfaces and bottom surfaces of the through holes 221; and removing the initial catalyst layer located on the bottom surfaces of the through holes 221 to form the catalyst layer.

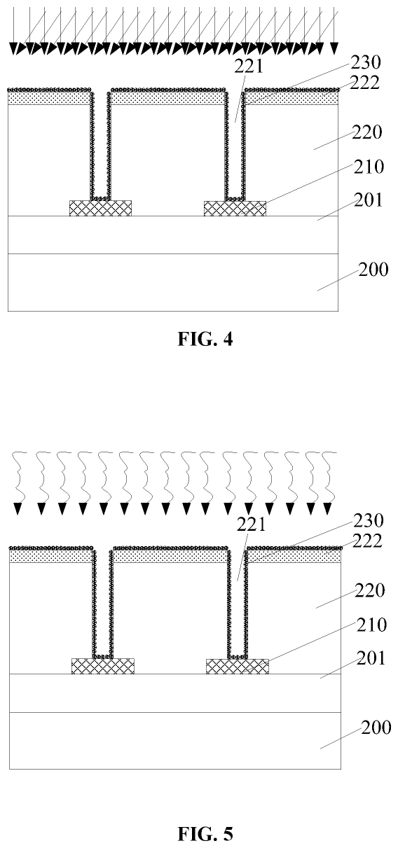

Returning to FIG. 23, after forming the interlayer dielectric layer, an initial catalyst layer may be formed (S103). FIG. 4 illustrates a corresponding structure.

As shown in FIG. 4, an initial catalyst layer 230 may be formed on the sidewall surfaces and the bottom surfaces of the through holes 221. The initial catalyst layer 230 may be formed by performing an ion implantation process to implant the catalytic ions into the sidewall surfaces and the bottom surfaces of the throughs holes 221.

The catalytic ions may be cobalt ions, iron ions, or nickel ions, etc. The ion implantation process may be performed from a plurality of implantation directions including a tilt direction and a direction perpendicular to the surface of the base substrate 200 to implant the catalytic ions into the sidewall surfaces and the bottom surfaces of the through holes 221.

In one embodiment, the through hole mask layer 222 may be able to prevent the ion implantation process from implanting the catalytic ions into the top surface of the interlayer dielectric layer 220.

In one embodiment, the initial catalyst layer 230 may be formed by an ion implantation process. The advantage using the ion implantation process may include that certain gaps may be formed between the particles in the initial catalytic layer 230, and the particles may not be substantially dense. Accordingly, it may facilitate to substantially grow carbon nanotubes on the sidewall surfaces of the through holes 221.

Returning to FIG. 23, after forming the initial catalyst layer, an annealing process may be performed (S104). FIG. 5 illustrates a corresponding structure.

As shown in FIG. 5, after performing the ion implantation process to form the initial catalyst layer 230, an annealing process may be performed on to the initial catalyst layer 230. The annealing temperature may be in a range of approximately 200° C.-500° C., such as 200° C., 300° C., 400° C., or 500° C., etc.

The annealing process may be able to enhance the bonding force between the initial catalyst layer 230 and the sidewall surfaces and the bottom surfaces of the through holes 221 to facilitate the subsequent growth of carbon nanotubes on the sidewall surfaces of the through holes 221.

In some embodiments, the initial catalyst layer may not be annealed. In other embodiments, the initial catalytic layer may be formed by a deposition process, such as a molecular beam epitaxial growth (MBE) process, or a sputter deposition process, etc.

In one embodiment, the initial catalyst layer 230 may also be formed on the interlayer dielectric layer 220. In particular, the initial catalyst layer 230 may also be formed on the top surface and the sidewall surfaces of the through hole mask layer 222.

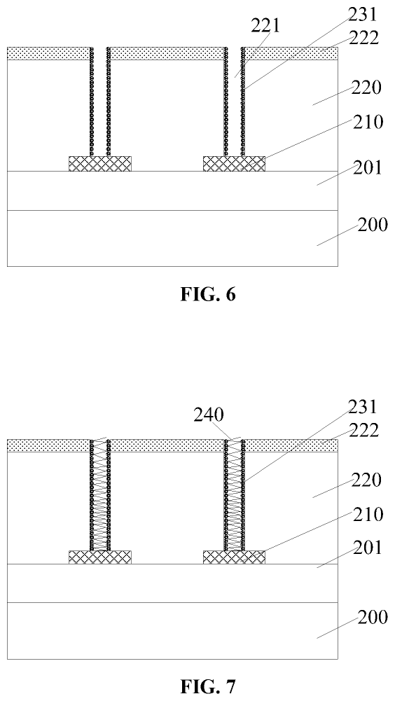

Returning to FIG. 23, after performing the annealing process, a catalyst layer may be formed (S105). FIG. 6 illustrates a corresponding structure.

As shown in FIG. 6, after the annealing process, the portions of the initial catalyst layer 230 on the bottom surfaces of the through holes 221 may be removed to form a catalyst layer 231. The catalyst layer 231 may be on the sidewall surfaces of the through holes 221; and the catalyst layer 231 may not be formed on the bottom surfaces of the through holes 221.

In one embodiment, the initial catalyst layer 230 on the interlayer dielectric layer 220 may be removed while removing the portions of the initial catalyst layer 230 on the bottom surfaces of the through holes 221. In particular, the portion of the initial catalyst layer 230 on the top surface of the through hole mask layer 222 may be removed. The process for removing the portions of the initial catalyst layer 230 on the bottom surfaces of the through holes 221 and the portion of the initial catalyst layer 230 on the interlayer dielectric layer 220 may include an anisotropic dry etching process, etc.

The catalyst layer 231 may be made of any appropriate material, such as cobalt nanoparticles, iron nanoparticles, or nickel nanoparticles, etc. Such nanoparticles may have the advantages of desired catalytic performance, and high catalytic efficiency, etc.

In one embodiment, the catalyst layer 231 may be formed by first forming the initial catalyst layer 230; and then removing the portions of the initial catalyst layer 230 on the bottom surfaces of the through hole 221 and the portion of the initial catalyst layer 230 on the interlayer dielectric layer 220. The ion implantation process for forming the initial catalyst layer 230 may not require a precise control of the implantation angles. Thus, the process difficulty may be reduced. Further, it may be easy to remove the portions of the initial catalyst layer 230 on the bottom surfaces of the through holes 221 and the portion of the initial catalyst layer 230 on the interlayer dielectric layer 220. In summary, the process difficulty may be reduced.

In some embodiments, catalytic ions may be implanted into the sidewall surfaces of the through holes by an ion implantation process, but the catalytic ions may not be implanted into the bottom surfaces of the through holes. The implantation direction of the ion implantation process may have a certain inclining angle with the surface of the base substrate to form the catalyst layer. In such a case, it may be necessary to precisely control the implantation angle of the ion implantation process so that the catalytic ions may not be implanted into the bottom surfaces of the through holes. However, the process steps of such a method may be simplified.

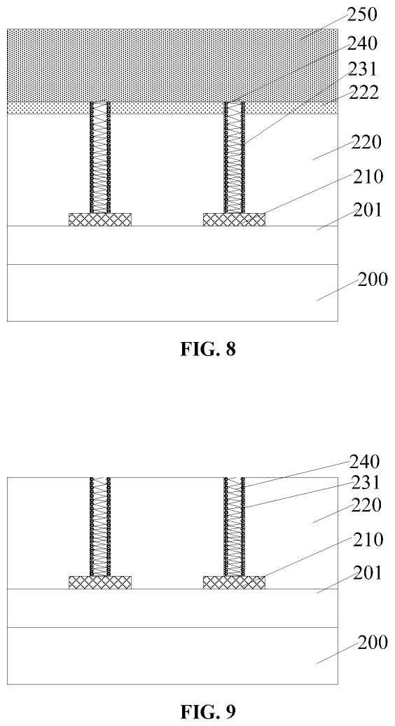

Returning to FIG. 23, after forming the catalyst layer, a carbon nanotube layer may be formed (S106). FIG. 7 illustrates a corresponding structure.

As shown in FIG. 7, after forming the catalyst layer 231, a carbon nanotube layer 240 may be formed in the through holes 221. The carbon nanotube layer 240 may be formed by any appropriate process, such as a catalytic chemical vapor deposition, etc.

In one embodiment, the method for forming the carbon nanotube layer 240 in the through holes 221 by the catalytic chemical vapor deposition may include introducing a carbon source gas into the through holes 221. The carbon source gas may be dissociated into free carbon atoms and deposit into the through holes 221 to form the carbon nanotube layer 240 under the catalytic function of the catalyst layer 231.

The carbon source gas may include any appropriate gas. In one embodiment, the carbon source gas may include at least one of CO₂ and CF₄. The temperature of the catalytic chemical vapor deposition method may be in a range of approximately 300° C.-600° C., such as 300° C., 400° C., 500° C., or 600° C., etc.

In one embodiment, because the size of the through holes 221 may be substantially small, the amount of the carbon nanotube layer 240 formed in each of the through holes 221 may be substantially small. To ensure the controllability of the fabrication process, it may be necessary to form the carbon nanotube layer 240 at a relatively low temperature. Further, because the catalyst layer 231 may be formed by an ion implantation process, the particles in the initial catalytic layer 230 may not be excessively dense, the temperature required for the formation of the carbon nanotube layer 240 may also be reduced

In one embodiment, the temperature of the catalytic chemical vapor deposition process for forming the carbon nanotube layer 240 may be substantially low. Thus, the heat influence on the device formed in the base substrate 200 may be substantially small.

Further, the chamber pressure of the catalytic chemical vapor deposition process may be in a range of approximately 8 atm-10 atm. Such a chamber pressure may be able to increase the deposition rate of the carbon nanotube layer 240. In some embodiments, the chamber pressure of the catalytic chemical vapor deposition process may be other appropriate value.

Because the carbon nanotube layer 240 may be formed under the catalytic action of the catalyst layer 231 on the sidewall surfaces of the through holes 221, the length (extending) direction of the carbon nanotubes in the carbon nanotube layer 240 may substantially coincides with the radial directions of the through holes 221. In particular, the angle between the length directions of the carbon nanotubes in the carbon nanotube layer 240 and the radial directions of the through holes 221 may be in a range of 0-45°, such as 0°, 5°, 10°, 20°, 30°, 40°, or 45°, etc.

In one embodiment, the carbon nanotube layer 240 may also extend outside the through holes 221.

Returning to FIG. 23, after forming the carbon nanotube layer, a polishing layer may be formed (S107). FIG. 8 illustrates a corresponding structure.

As shown in FIG. 8, a polishing layer 250 may be formed on the interlayer dielectric layer 220 and the carbon nanotube layer 240.

The material of the polishing layer 250 may be different from the material of the through hole mask layer 222, and may be different from the material of the interlayer dielectric layer 220. The material of the polishing layer 250 may include silicon nitride, or aluminum oxide, etc.

Returning to FIG. 23, after forming the polishing layer, a planarization process may be performed (S108). FIG. 9 illustrates a corresponding structure.

As shown in FIG. 9, a planarization process may be performed on the polishing layer 250 and the carbon nanotube layer 240 until the surface of the interlayer dielectric layer 220 is exposed. The planarization process may be a chemical mechanical polishing (CMP) process, etc.

In one embodiment, the through hole mask layer 222 may also be removed during planarizing the polishing layer 250 and the carbon nanotube layer 240.

In one embodiment, the carbon nanotube layer 240 may extend outside the through holes 221. The material of the polishing layer 250 may be filled among the carbon nanotubes outside the through holes 221, but the material of the polishing layer 250 may not be filled among the carbon nanotube layer 240 in the through holes 221. Thus, during polishing the carbon nanotube layer 240, the material of the polishing layer 250 among the carbon nanotubes outside the through holes 221 may also be polished. Accordingly, the polishing force on the carbon nanotubes may be uniform. After polishing the carbon nanotube layer 240, the top surface of the carbon nanotube layer 240 in the through holes 221 may be substantially flat and may have few defects. Thus, the interface state between the carbon nanotube layer 240 and the subsequently formed second conductive layer may be substantially low; and the electrical conductivity between the carbon nanotube layer 240 and the second conductive layer may be as desired.

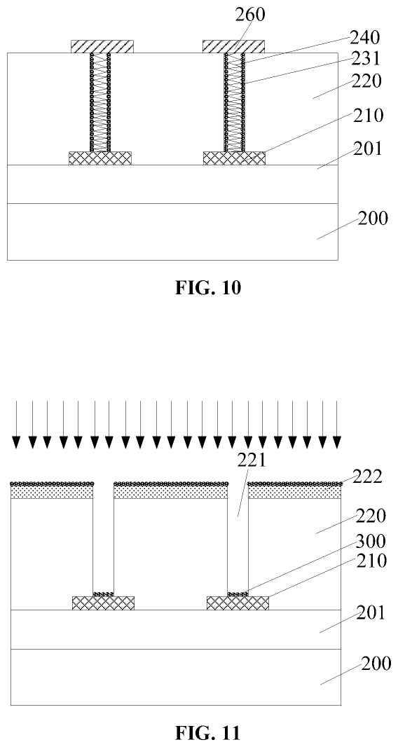

Returning to FIG. 23, after performing the planarization process, a second conductive layer may be formed (S109). FIG. 10 illustrates a corresponding structure.

As shown in FIG. 10, a second conductive layer 260 may be formed on the carbon nanotube layer 240 and a portion of the interlayer dielectric layer 220. The second conductive layer 260 may be made of any appropriate material, such as Ti, or Pt, etc.

When an off-state voltage is applied between the first conductive layer 210 and the second conductive layer 260, an electric current may be generated in the carbon nanotube layer 240 under the action of the off-state voltage; and the carbon nanotube layer 240 may be heated to further cause the carbon nanotubes in the carbon nanotube layer 240 to generate a thermal expansion. The thermal expansion may be represented by the repulsive force among the carbon nanotubes. When the repulsive force among the carbon nanotubes is greater than the van der Waals attraction among the carbon nanotubes, the distances between some of the carbon nanotubes may be increased; and the portion of the carbon nanotube layer 240 adjacent to the first conductive layer 210 and the portion of the carbon nanotube layer 240 adjacent to the second conductive layer 260 may be spatially disconnected; and the resistance of the carbon nanotube layer 240 may be increased. Under such a condition, the carbon nanotube layer 240 may present a high-impedance state; and the non-volatile memory may present an off-state.

When an on-state voltage is applied between the first conductive layer 210 and the second conductive layer 260, an electric field may be generated between the first conductive layer 210 and the second conductive layer 260 under the action of the on-state voltage. Under the action of the electric field, the distances between the portion of the carbon nanotube layer 240 near the first conductive layer 210 and the portion the carbon nanotube layer 240 near the second conductive layer 260 between the broken carbon nanotubes may be reduced. Thus, the originally spatially broken carbon nanotube layer 240 may be connected together; and the resistance of the carbon nanotube layer 240 may be substantially small. Under such a condition, the carbon nanotube layer 240 may exhibit a low resistance state; and the non-volatile memory may exhibit an on-state.

The on-state voltage may greater than the off-state voltage. In one embodiment, the off-state voltage may be in a range of approximately 1 volt to 2 volts. In one embodiment, the switch time may be in a range of approximately 1 ns-1 μs.

In one embodiment, the catalyst layer 231 may be formed on the sidewall surfaces of the through holes 221; and then the carbon nanotube layer 240 may be formed in the through holes 221 by the catalytic chemical vapor deposition. The carbon nanotube layer 240 in different through holes 221 may be formed based on the catalytic function of the catalyst layer 231 on the sidewall surfaces of the through holes 221. Thus, the distribution of the carbon nanotubes in the carbon nanotube layer 240 in the different through holes 221 may be substantially uniform; and the electrical properties of the carbon nanotube layer 240 in the different through holes 221 may be substantially uniform. Correspondingly, the off-state voltages of the carbon nanotube layer 240 in the different through holes 221 may be substantially uniform; and the performance of the non-volatile memory may be improved.

In one embodiment, in the carbon nanotube layer 240, the length (extending) direction of the carbon nanotubes may be substantially the same as the radial directions of the through holes 221. Thus, the distribution of the carbon nanotubes may be relatively regular. Further, the opening size of the through holes 221 may be in a range of approximately 5 nm-30 nm; and may substantially small. Thus, the off-state voltage of the non-volatile memory may be substantially low; and the power consumption may be reduced.

The present disclosure also provides a non-volatile memory. FIG. 10 illustrates a corresponding structure of a non-volatile memory consistent with various disclosed embodiments.

As shown in FIG. 10, the non-volatile memory may include a base substrate 200; a first conductive layer 210 formed on a surfaces of the base substrate 200; and an interlayer dielectric layer 220 formed on the base substrate 200 and the first conductive layer 210. The interlayer dielectric layer 220 may be have a plurality of through holes 221; and the through holes 221 may be disposed on the first conductive layer 210. Further, the non-volatile memory may include a carbon nanotube layer 240 in the through holes 221; and a catalyst layer 231. The catalyst layer 231 may be formed on at least one of sidewall surfaces and bottom surfaces of the through holes 221; and the catalyst layer 221 may be around the carbon nanotube layer 240. Further, the non-volatile memory may include a second conductive layer 260 formed on the nanotube layer 240 and a portion of the interlayer dielectric layer 220. The detailed structures and intermediate structures are described above with respect to the fabrication processes.

In one embodiment, the catalyst layer 231 may be formed on the sidewall surfaces of the through holes 221 and may be between the carbon nanotube layer 240 and the interlayer dielectric layer 220; and the catalyst layer 231 may not be formed between the carbon nanotube layer 240 and the first conductive layer 210.

In one embodiment, in the carbon nanotube layer 240, the length direction of the carbon nanotubes may substantially coincide with the radial direction of the through holes 221. In particular, the angle between the length direction of the carbon nanotubes in the carbon nanotube layer 240 and the radial direction of the through holes 221 may be in a range of approximately 0-45°.

The present disclosure along provides another method for forming a non-volatile memory. The difference between this method and the previous method may include that the catalyst layer may be formed on the bottom surfaces of the through holes, and may not be formed on the sidewall surfaces of the through holes.

FIGS. 11-16 illustrate structures corresponding to certain stages during another exemplary fabrication process for forming a non-volatile memory consistent with various disclosed embodiments.

FIG. 11 is a schematic diagram based on FIG. 3. As show in FIG. 11, the catalytic ions may be implanted into the bottom surfaces of the through holes 221 by an ion implantation process, and the catalytic ions may not be implanted into the sidewall surfaces of the through holes 221. The implantation direction of the ion implantation process may be perpendicular to the surface of the base substrate 200 to form the catalyst layer 300; and the catalyst layer 300 may be formed on the bottom surfaces of the through holes 221; and the catalyst layer 300 may not be formed on the sidewall surfaces of the through holes 221.

The catalytic ions may be cobalt ions, iron ions, or nickel ions, etc.

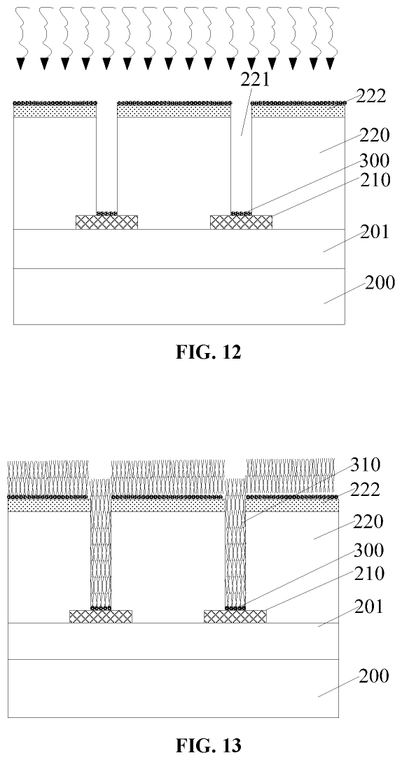

Further, as shown in FIG. 12, after the ion implantation process, the catalyst layer 300 may annealed. The annealing process may be referred to the annealing treatment of the previous embodiments.

In some embodiments, the catalyst layer may not be annealed.

In one embodiment, the catalyst layer 300 may also be formed on the interlayer dielectric layer 220. In particular, the catalyst layer 300 may also be formed on the top surface of a through hole mask layer 222. The catalyst layer 300 may not be formed on the sidewall surfaces of the through hole mask layer 222.

Further, as shown in FIG. 13, after forming the catalyst layer 300, the carbon nanotube layer 310 may be formed in the through holes 221 by a catalytic chemical vapor deposition process.

The process for forming the carbon nanotube layer 310 in the through holes 221 by the catalytic chemical vapor deposition may include introducing a carbon source gas into the through holes 221; and dissociating the carbon source gas into free carbon atoms under the catalytic action of the catalyst layer 300 and depositing the free carbon atoms in the through holes 221 to form the carbon nanotube layer 310.

The parameters of the catalytic chemical vapor deposition method may be referred to the previous embodiments.

Because the carbon nanotube layer 310 may be formed under the catalytic action of the catalyst layer 300 on the bottom surfaces of the through holes 221, the length direction of the carbon nanotubes in the carbon nanotube layer 310 may substantially coincide with the normal direction of the surface of the base substrate 200. The angle between the length directions of the carbon nanotubes in the carbon nanotube layer 310 and the normal direction of the surface of the base substrate 200 may be in a range of approximately 0° to 45°, such as 0°, 5°, 10°, 20°, 30°, 40°, or 45°, etc.

In one embodiment, the carbon nanotube layer 310 may extend outside the through holes 221. Correspondingly, the carbon nanotube layer 310 may also be formed on the through hole mask layer 222.

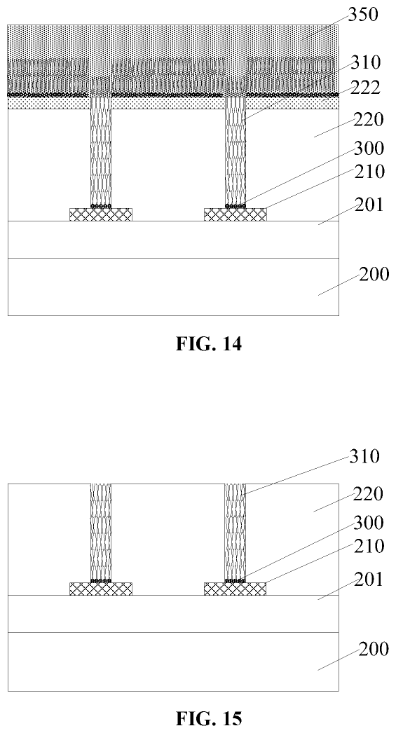

Further, as shown in FIG. 14, a polishing layer 350 may be formed on the interlayer dielectric layer 220 and the carbon nanotube layer 310.

The material and the function of the polishing layer 350 may refer to the material and the function of the polishing layer 250 described previously.

Further, as shown in FIG. 15, the polishing layer 350 and the carbon nanotube layer 310 may be planarized using a chemical mechanical polishing (CMP) process until the surface of the interlayer dielectric layer 220 is exposed.

In one embodiment, the through hole mask layer 222 may also be removed during planarizing the polishing layer 350 and the carbon nanotube layer 310.

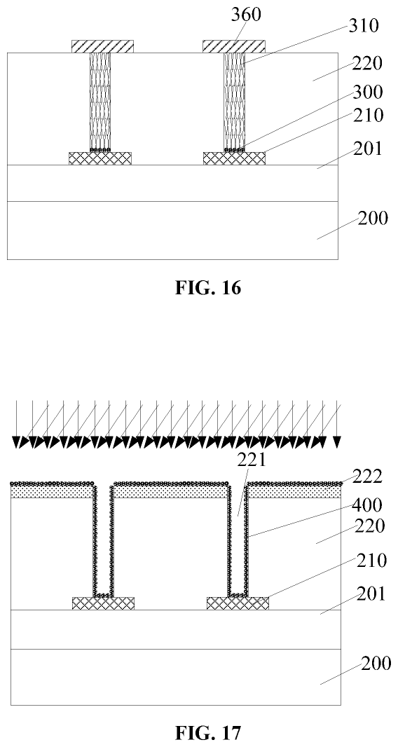

Further, as shown in FIG. 16, a second conductive layer 360 may be formed on the carbon nanotube layer 310 and a portion of the interlayer dielectric layer 220.

The operation principle of the non-volatile memory may refer to the operation principle of the previously described non-volatile memory.

In one embodiment, the carbon nanotube layer 310 in different through holes 221 may be formed under the catalytic action of the catalyst layer 300 on the bottom surfaces of the through holes 221. Thus, the distributions of the carbon nanotubes in the carbon nanotube layer 310 in the different through holes 221 may be substantially consistent. Accordingly, the electrical properties of the carbon nanotube layer 310 in the different through holes 221 may be substantially uniform. Correspondingly, the off-state voltages of the carbon nanotube layers 310 in the different through holes 221 may be substantially uniform; and the performance of the non-volatile memory may be improved.

In one embodiment, in the carbon nanotube layer 310, the length (extending direction) of the carbon nanotubes may be substantially the same as the normal direction of the surface of the base substrate 200. Thus, the distribution of the carbon nanotubes are substantially regular. Further, the opening size of the through holes 221 may be in a range of approximately 5 nm-30 nm; and the opening size of the through holes 221 may be substantially small. Thus, the on-state voltage of the non-volatile memory may be reduced; and the power consumption may be reduced. In one embodiment, the on-state voltage may be in a range of approximately 2 volts to 3 volts. In one embodiment, the switching time may be in a range of approximately 1 ns to 1 μs.

The present disclosure also provides another non-volatile memory. FIG. 16 illustrates a corresponding non-volatile memory.

As shown in FIG. 16, the difference between the non-volatile memory and the previously described non-volatile memory may include the position of the catalyst layer. In particular, the catalyst layer 300 may be formed on the bottom surfaces of the through holes 221; and may be between the carbon nanotube layer 310 and the first conductive layer 210. The catalyst layer 300 may not be formed between the carbon nanotube layer 310 and the interlayer dielectric layer 220.

In one embodiment, in the carbon nanotube layer 310, the length direction of the carbon nanotubes may substantially coincide with the normal direction of the surface of the base substrate 200. In particular, the angle between the length direction of the carbon nanotubes in the carbon nanotube layer 310 and the normal direction of the surface of the base substrate 200 may be in a range of approximately 0-45°.

Further, the present disclosure provides another method for forming a non-volatile memory. The difference between the method and the previously described methods may include that the catalyst layer may be formed on both the sidewall surfaces and the bottom surfaces of the through holes.

FIG. 17-22 illustrate structures corresponding certain stages during another exemplary fabrication process of a non-volatile memory consistent with various disclosed embodiments.

FIG. 17 illustrates a structure based on FIG. 3. As shown in FIG. 17, a catalyst layer 400 may be formed on the sidewall surfaces and the bottom surfaces of the through holes 221 by implanting catalytic ions using an ion implantation process. The catalyst layer 400 may be formed on both the sidewall surfaces and the bottom surfaces of the through holes 221.

The catalytic ions may be cobalt ions, iron ions, or nickel ions, etc.

The ion implantation process may be performed from a plurality of implantation directions including a tilt direction and a direction perpendicular to the surface of the substrate 200 to implant catalytic ions into the sidewall surfaces and the bottom surfaces of the through holes 221.

In one embodiment, the through hole mask layer 222 may be able to prevent the ion implantation process from implanting catalytic ions into the top surface of the interlayer dielectric layer 220.

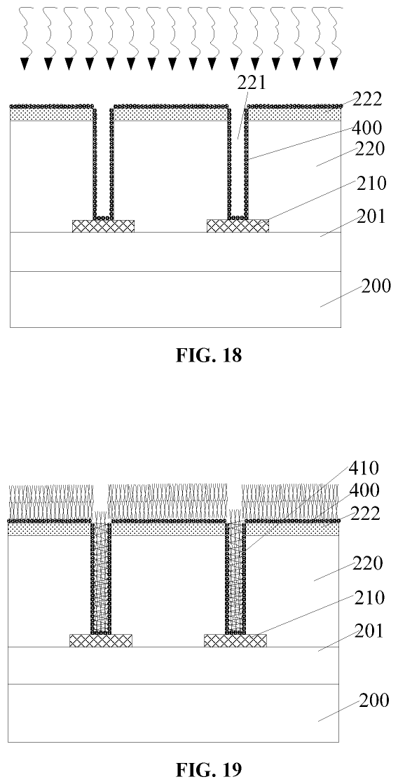

Further, as shown in FIG. 18, after the ion implantation process, the catalyst layer 400 may be annealed.

The parameters of the annealing process may refer to the parameters of the annealing treatment in the previous embodiments.

In some embodiments, the catalyst layer 400 may be formed by a deposition process, such as a molecular beam epitaxial growth (MBE) process, or a sputter deposition process, etc.

In one embodiment, the catalyst layer 400 may also be formed on the interlayer dielectric layer 220. In particular, the catalyst layer 400 may also be located on the top surface and the sidewall surfaces of the through hole mask layer 222.

Further, as shown in FIG. 19, after forming the catalyst layer 400, a carbon nanotube layer 410 may be formed in the through holes 221 by a catalytic chemical vapor deposition process.

The method for forming the carbon nanotube layer 410 in the through holes 221 by catalytic chemical vapor deposition may include introducing a carbon source gas into the through holes 221; and dissociating the carbon source gas under the catalytic action of the catalyst layer 400 into free carbon atoms and depositing the free carbon atoms in the through holes 221 to form the carbon nanotube layer 410.

The parameters of the catalytic chemical vapor deposition process may be referred to the previous descriptions.

In one embodiment, a portion of the carbon nanotube layer 410 may be formed under the catalytic action of the catalyst layer 400 on the sidewall surfaces of the through holes 221. In such a portion of the carbon nanotube layer 410, the length direction of the carbon nanotubes may be substantially the same as the radial direction of the through holes 221. In particular, in such a portion of the carbon nanotube layer 410, the angle between the length direction of the carbon nanotubes and the radial direction of the through holes 221 may be in a range of approximately 0° to 45°, such as 0°, 5°, 10°, 20°, 30°, 40°, or 45°, etc.

In one embodiment, a portion of the carbon nanotube layer 410 may be formed under the catalytic action of the catalyst layer 400 on the bottom surfaces of the through holes 221. In such a portion of the carbon nanotube layer 410, the length direction of the carbon nanotubes may be substantially the same as the normal direction of the base substrate 200. In particular, in such a portion of the carbon nanotube layer 410, the angle between the length direction of the carbon nanotubes and the normal direction of the base substrate 200 may be in a range of approximately 0° to 45°, such as 0°, 5°, 10°, 20°, 30°, 40°, or 45°, etc.

In one embodiment, the carbon nanotube layer 410 may also extend outside the through holes 221. The carbon nanotube layer 410 may also be formed on the through hole mask layer 222.

Further, as shown in FIG. 20, after forming carbon nanotube layer 410, a polishing layer 450 may be formed on the interlayer dielectric layer 220 and the carbon nanotube layer 410.

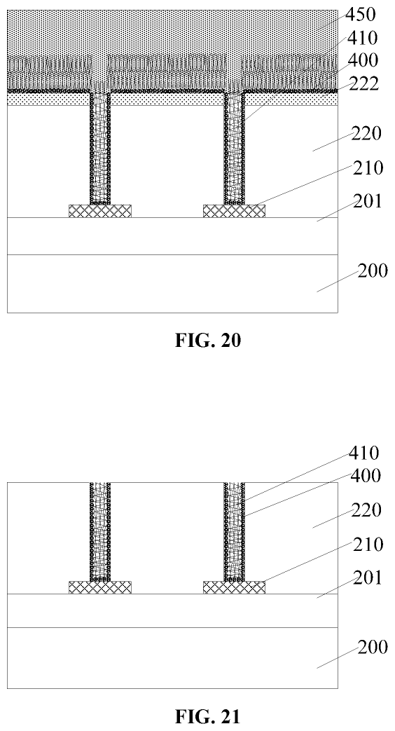

Further, as shown in FIG. 21, after forming the polishing layer 450, the polishing layer 450 and the carbon nanotube layer 410 may be planarized using a chemical mechanical polishing (CMP) process until the surface of the interlayer dielectric layer 220 is exposed. In one embodiment, the through hole mask layer 222 may be removed during planarizing the polishing layer 450 and the carbon nanotube layer 410.

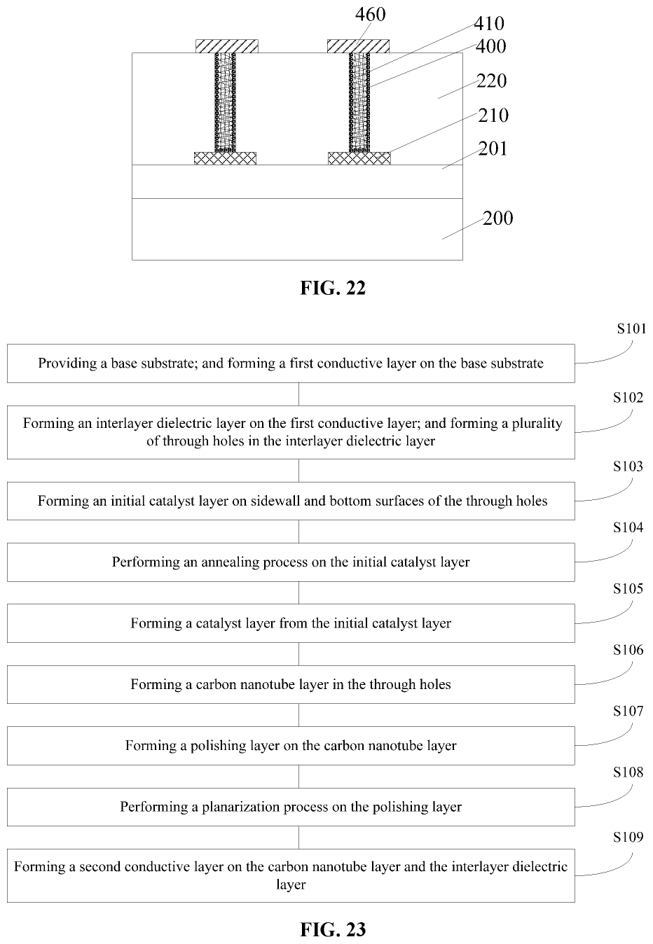

Further, as show in FIG. 22, after the planarization process, a second conductive layer 460 may be formed on the carbon nanotube layer 410 and a portion of the interlayer dielectric layer 220.

The operation principle of the non-volatile memory may be referred to the operation principle of the previously described non-volatile memory.

In one embodiment, the carbon nanotube layer 410 in different through holes 221 may be formed under the catalytic action of the catalyst layer 400 on the bottom surfaces of the through holes 221. Thus, the distribution of the carbon nanotubes in the carbon nanotube layer 410 in different through holes 221 may be substantially consistent. Accordingly, the electrical properties of the carbon nanotube layer 410 in the different through holes 221 may be relatively uniform. Correspondingly, the off-state voltage of the carbon nanotube layer 410 in the different through holes 221 may be substantially uniform; and the performance of the non-volatile memory may be improved.

In one embodiment, the distribution of the carbon nanotubes in the carbon nanotube layer 410 may be substantially regular. In particular, a portion of the carbon nanotube layer 410 may be formed under the catalytic action of the catalyst layer 400 on the sidewall surfaces of the through holes 221. The length direction of the carbon nanotubes in such a portion may substantially coincide with the radial direction of the through holes 221. Further, a portion of the carbon nanotube layer 410 may be formed under the catalytic action of the catalyst layer 400 on the bottom surfaces of the through holes 221, and the length direction of the carbon nanotubes in such a portion may substantially coincide with the normal direction of the surface of the base substrate 200. Further, the opening size of the through holes 221 may be substantially small; and may be in a range of approximately 5 nm-30 nm. Thus, the off-state voltage and the on-state voltage of the non-volatile memory may be reduced; and the power consumption of the non-volatile memory may be reduced. In one embodiment, the on-state voltage may be in range of approximately 2 volts to 3 volts; and the off-state voltage may be in a range of approximately 1 volt to 2 volts. In one embodiment, the switching time may be in a range of approximately 1 ns to 1 μm.

Further, the present disclosure provides another non-volatile memory. FIG. 22 illustrates a corresponding non-volatile memory consistent with various disclosed embodiments.

Comparing with previously described non-volatile memory, the position of the catalyst layer of the non-volatile memory of the present embodiment is different. In particular, the catalyst layer 400 may be formed between the carbon nanotube layer 410 and the interlayer dielectric layer 220, and between the carbon nanotube layer 410 and the first conductive layer 210.

In such an embodiment, a portion of the carbon nanotube layer 410 is formed under the catalytic action of the catalyst layer 400 on the sidewall surfaces of the through holes 221. In such a portion of the carbon nanotube layer 410, the length (extending) direction of the carbon nanotubes may substantially coincide with the radial direction of the through holes 221 Specifically, in such a portion of the carbon nanotube layer 410, the angle between the length direction of the carbon nanotubes and the radial direction of the through hole 221 may be in a range of approximately 0-45°.

In one embodiment, a portion of the carbon nanotube layer 410 is formed under the catalytic action of the catalyst layer 400 on the bottom surfaces of the through hole 221. In such a portion of the carbon nanotube layer 410, the length direction of the carbon nanotubes may be substantially the same as the normal direction of the surface of the base substrate 200. Specifically, in such a portion of the carbon nanotube layer 410, the angle between the length direction of the carbon nanotubes and the normal direction of the surface of the base substrate 200 may be in a range of approximately 0-45°.

In the disclosed method for forming a non-volatile memory, a catalyst layer may be formed on at least one of the sidewall surfaces and bottom surfaces of the through holes; and then a carbon nanotube layer may be formed in through holes by a catalytic chemical vapor deposition process. The carbon nanotube layer in different through holes may be formed under the catalytic action of the catalyst layer. Thus, the distribution of the carbon nanotubes in the carbon nanotube layer in different through holes may be substantially uniform; and the electrical properties of the carbon nanotube layer in different through holes may be substantially uniform. Correspondingly, the on-state voltages of the carbon nanotube layer in different through holes may be substantially uniform; and the off-state voltages of the carbon nanotube layer in different through holes may be substantially uniform. Thus, the performance of the non-volatile memory may be improved.

Further, the opening size of the through holes may be substantially small; may be in a range of approximately 5 nm to 30 nm. The distribution of the carbon nanotubes formed in each through hole by the catalytic chemical vapor deposition method may be substantially regular. Thus, the operating voltage of the non-volatile memory may be reduced. In particular, at least one of the on-state voltage and the off-state voltage of the non-volatile memory may be reduced.

The above detailed descriptions only illustrate certain exemplary embodiments of the present disclosure, and are not intended to limit the scope of the present disclosure. Those skilled in the art can understand the specification as whole and technical features in the various embodiments can be combined into other embodiments understandable to those persons of ordinary skill in the art. Any equivalent or modification thereof, without departing from the spirit and principle of the present disclosure, falls within the true scope of the present disclosure.

What is claimed is:

1. A method for fabricating a non-volatile memory, comprising:
providing a base substrate;
forming a first conductive layer on the base substrate;
forming an interlayer dielectric layer on the first conductive layer;
forming a plurality of through holes exposing the first conductive layer in the interlayer dielectric layer;
forming a catalyst layer on at least one of sidewall surfaces and bottom surfaces of the through holes;
forming a carbon nanotube layer in the through holes by a catalytic chemical vapor deposition process; and
forming a second conductive layer on the carbon nanotube layer and a portion of the interlayer dielectric layer.

2. The method according to claim 1, wherein forming the carbon nanotube layer in the through holes by the catalytic chemical vapor deposition process comprises:
introducing a carbon source gas into the through holes; and
disassociating the carbon source gas into free carbon atoms under an action of the catalyst layer and depositing the free carbon ions on the through holes to form the carbon nanotube layer.

3. The method according to claim 2, wherein:
the carbon source gas includes at least one of CO₂ and CF₄; and
a temperature of the catalytic chemical vapor deposition process is in a range of approximately 300° C.-600° C.

4. The method according to claim 1, wherein:
the catalyst layer is formed on only the sidewall surfaces of through holes.

5. The method according to claim 4, wherein forming the catalyst layer comprises:
implanting the catalytic ions into the sidewall surfaces and bottom surfaces of the through holes by an ion implantation process to form an initial catalyst layer on the sidewall surfaces and bottom surfaces of the through holes; and
removing portions of the initial catalyst layer on the bottom surfaces of the through holes to form the catalyst layer.

6. The method according to claim 4, wherein forming the catalyst layer comprises:
implanting the catalytic ions into only the sidewall surfaces of the through holes by an ion implantation process with a certain implantation angle with the base substrate to form the catalyst layer.

7. The method according to claim 1, wherein:
the catalyst layer is formed only on the bottom surfaces of the through holes.

8. The method according to claim 7, wherein forming the catalyst layer comprises:
implanting the catalytic ions into only the bottom surfaces of the through holes with an implantation direction perpendicular to a surface of the base substrate to form the catalyst layer.

9. The method according to claim 1, wherein:
the catalyst layer is formed on both sidewall surfaces and bottom surfaces of the through holes.

10. The method according to claim 9, wherein forming the catalyst layer comprises:
implanting the catalytic ions into both the sidewall surfaces and the bottom surfaces of the through holes to form the catalyst layer.

11. The method according to claim 1, before forming the carbon nanotube layer, further comprising:
annealing the catalyst layer.

12. The method according to claim 11, wherein:
an annealing temperature is in a range of approximately 200° C.-500° C.

13. The method according to claim 1, wherein:
the catalyst layer is made of one of cobalt nanoparticles, iron nanoparticles and nickel nanoparticles.

14. The method according to claim 1, wherein:
an opening size of the through holes is in a range of approximately 5 nm-30 nm; and
a height of the through holes is in a range of approximately 45 nm-52 nm.

15. The method according to claim 1, before forming the second conductive layer, further comprising:
forming a polishing layer on the interlayer dielectric layer and the carbon nanotube layer; and
planarizing the polishing layer and the carbon nanotube layer using a chemical mechanical polishing process until a surface of the interlayer dielectric layer is exposed.

16. The method according to claim 14, wherein:
the polishing layer is made of one of silicon nitride and aluminum nitride.

17. A non-volatile memory, comprising:
a base substrate;
a first conductive layer formed on the base substrate;
an interlayer dielectric layer formed on the base substrate and the first conductive layer, wherein the interlayer dielectric layer contains a plurality of through holes exposing the first conductive layer;
a carbon nanotube layer formed in the through holes;
a catalyst layer formed on at least one of sidewall surfaces and bottom surfaces of the through holes and around the carbon nanotube layer; and
a second conductive layer formed on the carbon nanotube layer and a portion of the interlayer dielectric layer.

18. The non-volatile memory according to claim 17, wherein:
the catalyst layer is made of one of cobalt nanoparticles, iron nanoparticles and nickel nanoparticles.

19. The non-volatile memory according to claim 17, wherein:
the first conductive layer is made of one of copper, aluminum, and copper aluminum alloy; and
the second conductive layer is made of one of titanium and platinum.

20. The non-volatile memory according to claim 17, wherein:
the interlayer dielectric layer is made of one of a low-K dielectric material, an ultra-low-K dielectric material and silicon oxide.
